(19) United States
(12) Patent Application Publication
(10) Pub. No.: US 2019/0096322 A1
(43) Pub. Date: Mar. 28, 2019

(54) PIXEL DRIVING CIRCUIT AND METHOD THEREOF, AND DISPLAY DEVICE

(71) Applicant: BOE TECHNOLOGY GROUP CO., LTD., Beijing (CN)

(72) Inventor: Xueling GAO, Beijing (CN)

(21) Appl. No.: 15/964,367

(22) Filed: Apr. 27, 2018

(30) Foreign Application Priority Data
Sep. 28, 2017 (CN) 201710895280.0

(51) Int. Cl. G09G 3/3233; G09G 3/3266; G09G 3/3275; H01L 27/32

(52) U.S. Cl. CPC G09G 3/3233; G09G 3/3266; H01L 27/3265; H01L 27/3262; G09G 3/3275

(57) ABSTRACT

The present disclosure provides a pixel driving circuit, a pixel driving method, and a display device. The pixel driving circuit includes: a first switch element, a second switch element, a third switch element, a fourth switch element, a fifth switch element, a sixth switch element, a driving transistor and a storage capacitor.

### CROSS-REFERENCE TO RELATED APPLICATIONS

This application claims priority to Chinese Patent Application No. 201710895280.0, filed Sep. 28, 2017, the entire contents of which are incorporated as a portion of the present application herein by reference.

### TECHNICAL FIELD

The present disclosure generally relates to a field of display technology, and more particularly, to a pixel driving circuit, a pixel driving method, and a display device.

### BACKGROUND

As a current mode light-emitting device, OLED (organic light emitting diode) is more and more applied in the field of high performance display because of its characteristic of self-luminescence, fast response, wide viewing angle and can be made on the flexible substrate etc. The OLED display screen is made of organic light-emitting diodes. The OLED display screen is considered to be the next generation of new applied technology for flat panel display because of its excellent characteristics of self-luminescence, no backlight source, high contrast, thin thickness, wide angle of view, fast reaction speed, applicability for flexible panel, wide range of using temperature, simple construction and simple process etc.

At present, due to the hysteresis effect of the driving transistor in pixel driving circuit, it makes the OLED display screen displaying a short term of residual image when switching to a 48 gray scales picture after lighting a black-and-white picture for a period of time. The so-called hysteresis effect is mainly caused by the shift of threshold voltage due to the residual mobile ions, when VGS (the voltage between the gate of a transistor and the source of the transistor) is smaller (that is, more negative), the ACT/GI interface will catch more charge, therefore, the threshold voltage generates negative bias; when VGS (the voltage between the gate of a transistor and the source of the transistor) is greater (that is, more positive), the charge captured by the ACT/GI interface will be released, therefore, the threshold voltage generates positive bias. In the current pixel driving circuit, in the case of the switching of different pictures, the VGS (the voltage between the gate of a transistor and the source of the transistor) of initialization phase of driving transistor is different, thus the state of the residual mobile ions is different, resulting in the short term residual image.

Therefore, it is needed to provide a pixel driving circuit to eliminate the residual image.

It should be noted that the information disclosed in the above background technology part is used only to strengthen the understanding of the background of the present disclosure, and thus may include information that does not constitute the existing technology known to ordinary technical personnel in the field.

### SUMMARY

According to one aspect of the present disclosure, there is provided a pixel driving circuit, which is configured to drive an electroluminescent element, and the pixel driving circuit including:

a first switch element, which is connected to a first node, and is configured for conduction in response to a first scanning signal, so as to transmit a reset signal to the first node;

a second switch element, which is connected to a second node, and is configured for conduction in response to the first scanning signal, so as to transmit the reset signal to the second node;

a third switch element, which is connected to a fourth node, and is configured for conduction in response to a second scanning signal, so as to transmit a data signal to the fourth node;

a fourth switch element, which is connected to the fourth node, and is configured for conduction in response to a control signal, so as to transmit a first power signal to the fourth node;

a fifth switch element, which is connected to the second node and a third node, and is configured for conduction in response to the control signal, so as to interconnect the third node to the second node, and the second node is coupled with the electroluminescent element;

a sixth switch element, which is connected with the first node and the third node, and is configured for conduction in response to the second scanning signal, so as to interconnect the first node to the third node;

a drive transistor, which is connected to the third node and the fourth node, and is configured for conduction in response to a voltage signal of the first node, so as to transmit a signal of the fourth node to the third node;

a storage capacitor, a first end of the storage capacitor is coupled with the first node, and a second end of the storage capacitor receives the first power signal.

According to one aspect of the present disclosure, there is provided a pixel driving method, which is configured to drive any of the pixel driving circuit that mentioned above, the method including:

a reset stage, the first switch element, the second switch element, the fourth switch element and the fifth switch element are turned on through the first scanning signal and the control signal; the reset signal is transmit to the first node through the first switch element, and the drive transistor is turned on through the voltage signal of the first node; the reset signal is transmit to the second node through the second switch element and the reset signal is transmit to the third node through the fifth switch element; the first power signal is transmit to the fourth node through the fourth switch element;

a data writing and threshold compensation stage, the third switch element and the sixth switch element are turned on through the second scanning signal, so as to write the data signal and a threshold voltage of the drive transistor to the first node;

a driving stage, the fourth switch element and the fifth switch element are turned on through the control signal, so as to turn on the driving transistor under the control of the voltage of the first node and output a driving current under the action of the first power signal, and the driving current flows through the fifth switch element to drive the electroluminescent element to emit light.

According to one aspect of the present disclosure, there is provided a display device, including any one of the pixel driving circuit mentioned above.

### BRIEF DESCRIPTION OF THE DRAWINGS

The above and other characteristics and advantages of the present disclosure will be more obvious by referring to the accompanying drawings to describe their exemplary embodiments in detail. Obviously, the following illustration is only some embodiments of the present disclosure, for the general technical personnel in this field, other drawings can also be obtained on the basis of these drawings under the premise of not paying creative work, in the accompanying drawings:

FIG. 1 is a schematic diagram of pixel driving circuit provided in an exemplary embodiment of the present disclosure;

FIG. 2 is a working timing diagram of pixel driving circuit provided in an exemplary embodiment of the present disclosure;

FIG. 3 is an equivalent circuit diagram in the reset stage of pixel driving circuit provided in an exemplary embodiment of the present disclosure;

FIG. 4 is an equivalent circuit in the data writing and threshold compensation stage of pixel driving circuit provided in an exemplary embodiment of the present disclosure;

FIG. 5 is an equivalent circuit in the driving stage of pixel driving circuit provided in an exemplary embodiment of the present disclosure.

### DETAILED DESCRIPTION

Now, there will be given a more comprehensive description of exemplary embodiments with reference to the accompanying drawings. However, the exemplary embodiments can be implemented in many ways, and should not be interpreted as limited to the embodiments described herein; on the contrary, the these embodiments will make the present disclosure comprehensive and complete, and make the idea of the exemplary embodiments comprehensively conveying to the technicians in this field. The characteristics, structures or characteristics described can be combined in one or more embodiments in any suitable way. In the following description, there will provide many specific details to give a full understanding of the embodiments of the present disclosure. However, technicians in the field will realize that, can practice the technical scheme of the present disclosure without one or more of the specific details, or can use other methods, components, materials, devices, steps etc. In other cases, the well-known technology solutions are not shown or described in detail, so as to avoid blurring any aspect of the present disclosure.

Besides, the accompanying drawings are only schematic diagrams of the present disclosure, not necessarily plotted in proportion. The following description refers to the accompanying drawings in which the same numbers in different drawings represent the same or similar elements, thus the repeated descriptions of them will be omitted.

The present exemplary embodiment provides a pixel driving circuit, which is configured to drive an electroluminescent element. As shown in FIG. 1, the pixel driving circuit may include: a first switch element T1, a second switch element T2, a third switch element T3, a fourth switch element T4, a fifth switch element T5, a sixth switch element T6, a drive transistor DT and a storage capacitor C.

The first switch element T1 is connected to a first node N1, and may be configured to be turned on in response to a first scanning signal G1, so as to transmit a reset signal to the first node N1. The second switch element T2 is connected to a second node N2, and may be configured to be turned on in response to the first scanning signal G1, so as to transmit the reset signal to the second node N2. The third switch element T3 is connected to a fourth node N4, and may be configured to be turned on in response to a second scanning signal G2, so as to transmit a data signal DATA to the fourth node N4. The fourth switch element T4 is connected to the fourth node N4, and may be configured to be turned on in response to a control signal EM, so as to transmit a first power signal ELVDD to the fourth node N4. The fifth switch element T5 is connected to the second node N2 and a third node N3, and may be configured to be turned on in response to the control signal EM, so as to interconnect the third node N3 to the second node N2, and the second node N2 is coupled with the electroluminescent element. The sixth switch element T6 is connected to the first node N1 and the third node N3, and may be configured to be turned on in response to the second scanning signal G2, so as to interconnect the first node N1 to the third node N3. The drive transistor DT is connected to the third node N3 and the fourth node N4, and may be configured to be turned on in response to a voltage signal of the first node N1, so as to transmit a signal of the fourth node N4 to the third node N3. A first end of the storage capacitor C is coupled with the first node N1, and a second end of the storage capacitor C receives the first power signal ELVDD. In a reset stage, the pixel driving circuit can reset a control end of the drive transistor DT, and change a voltage of a first end of the driving transistor DT to a voltage of the first power signal ELVDD, so that the driving transistor DT in the basis state enters a data writing and threshold compensation stage, thus improving the problem of short term residual image caused by hysteresis effect, and improving the quality of display. In addition, in the reset stage, by turning on the second switch element T2 through the first scanning signal G1, making the reset signal VINT transmit to the second node N2 through the second switch element T2, so as to reduce the voltage difference between a first electrode and a second electrode of the electroluminescent element, the brightness of the electroluminescent element can be reduced in low gray scales, improving the contrast of pixels. In addition, in the data writing and threshold compensation stage, the pixel driving circuit may write the data signal DATA and a threshold voltage of the driving transistor DT to the first node N1, so as to eliminate the influence of the threshold voltage of the driving transistor DT on a driving current, and ensure the uniformity of the brightness of each pixel. Next, there will be given a more detailed description of the pixel driving circuit with reference to FIG. 1.

In the present exemplary embodiment, the first switch element T1 to the sixth switch element T6 and the driving transistor DT have a control end, a first end and a second end respectively.

The control end of the first switch element T1 receives the first scanning signal G1, the first end of the first switch element T1 is coupled with the first node N1, and the second end of the first switch element T1 receives the reset signal VINT. The control end of the second switch element T2 receives the first scanning signal G1, the first end of the second switch element T2 is coupled with the second node N2, and the second end of the second switch element T2 receives the reset signal VINT. The control end of the third switch element T3 receives the second scanning signal G2, the first end of the third switch element T3 receives the data signal DATA, and the second end of the third switch element T3 is coupled with the fourth node N4. The control end of the fourth switch element T4 receives the control signal EM, the first end of the fourth switch element T4 receives the first power signal ELVDD, and the second end of the fourth switch element T4 is coupled with the fourth node N4. The control end of the fifth switch element T5 receives the control signal EM, the first end of the fifth switch element T5 is coupled with the third node N3, and the second end of the fifth switch element T5 is coupled with the second node N2. The control end of the sixth switch element T6 receives the second scanning signal G2, the first end of the sixth switch element T6 is coupled with the first node N1, and the second end of the sixth switch element T6 is coupled with the third node N3. The control end of the driving transistor DT is coupled with the first node N1, the first end of the driving transistor DT is coupled with the fourth node N4, and the second end of the driving transistor DT is coupled with the third node N3.

In the present exemplary embodiment, the first switch element T1 to the sixth switch element T6 can correspond to a first switch transistor to a sixth switch transistor respectively. Each switch transistor has a control end, a first end and a second end respectively. For example, the control end of each switch transistor may be a gate, the first end of each switch transistor may be a source, and the second end of each switch transistor may be a drain. As another example, the control end of each switch transistor may be a gate, the first end of each switch transistor may be a drain, and the second end of each switch transistor may be a source. In addition, each switch transistor may be enhanced type transistor or depleted type transistor, whereas the present exemplary embodiment does not make a special limit to this. It should be noted that, due to the symmetry of the source and the drain of the switch transistor, thus, the source and the drain of the first switch transistor to the sixth switch transistor may be interchanged.

The driving transistor DT has a control end, a first end and a second end. For example, the control end of the driving transistor DT may be a gate, the first end of the driving transistor DT may be a source, the second end of the driving transistor DT may be a drain. As another example, the control end of the driving transistor DT may be a gate, the first end of the driving transistor DT may be a drain, the second end of the driving transistor DT may be a. source. In addition, the driving transistor DT may be enhanced type transistor or depleted type transistor, the present exemplary embodiment does not make a special limit to this.

The type of the storage capacitor C may be selected according to the specific circuit. For example, the storage capacitor C may be MOS capacitor, metal capacitor or double polycrystalline capacitor, however, the storage capacitor in the present exemplary embodiment is not limited to this.

The electroluminescent element may be electroluminescent element, for example, OLED, driven by current, and controlled to emit light by the current that flows through the driving transistor DT. However, the electroluminescent element in the present exemplary embodiment is not limited to this. In addition, the electroluminescent element has a first electrode and a second electrode. For example, the first electrode of the electroluminescent element may be an anode, the second electrode of the electroluminescent element may be a cathode. As another example, the first electrode of the electroluminescent element may be a cathode, the second electrode of the electroluminescent element may be an anode.

In an array of multiple pixel driving circuits, in order to reuse the first scanning signal G1 and the second scanning signal G2 in each pixel driving circuit, so as to simplify the circuit structure of the array of multiple pixel driving circuits and realize scanning line-by-line. The pixel driving circuit is connected to line N and line N+1 of scan signal lines; wherein, line N of scan signal line is configured to output the first scanning signal G1, line N+1 of scan signal line is configured to output the second scanning signal G2; where N is a positive integer. Specially, the control end of the first switch element T1 and the control end of the second switch element T2 of the pixel driving circuit are connected to the line N of scan signal line, and the control end of the third switch element T3 and the control end of the sixth switch element T6 of the pixel driving circuit are connected to the line N+1 of scan signal line.

When the switch element (namely the first switch element to the sixth switch element T1˜T6) and the driving transistor DT are all P type thin film transistors, the first power signal ELVDD is a high level signal, the anode of the electroluminescent element is coupled with the second node N2, the cathode of the electroluminescent element receives a second power signal ELVSS, the cathode of the electroluminescent element receives a low level signal, namely, the second power signal ELVSS is a low level signal.

When the switch element (namely the first switch element to the sixth switch element T1˜T6) and the driving transistor DT are all N type thin film transistors, the first power signal ELVDD is a low level signal, the cathode of the electroluminescent element is coupled with the second node N2, the anode of the electroluminescent element receives a second power signal ELVSS, the anode of the electroluminescent element receives a high level signal, namely, the second power signal ELVSS is a high level signal.

Further, the type of the thin film transistors can be selected according to the specific requirements of the circuit. For example, the thin film transistors can be one of amorphous silicon thin film transistors, polycrystalline silicon thin film transistors, and amorphous-indium gallium zinc thin film transistors, however, the thin film transistors in this exemplary embodiment are not limited to this.

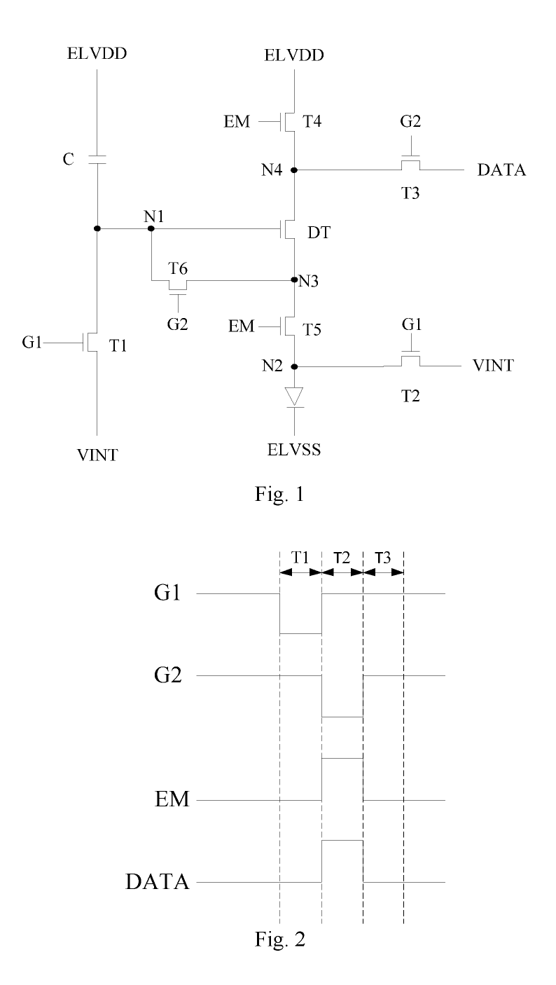

In the present exemplary embodiment, a pixel driving method is also provided, which is configured to drive the pixel driving circuit as described in FIG. 1. Next, combined with the working timing diagram of pixel driving circuit shown in FIG. 2, there will be given a detailed explanation of the working process of the pixel driving circuit in FIG. 1, taking all the switch elements and the driving transistor DT being P type thin film transistors as an example. Because all the switch elements are P type thin film transistors, the turned on signals of all the switch elements are low level signal. The first power signal ELVDD is a high level signal, and the second power signal ELVSS is a low level signal. The driving timing diagram illustrates the first scanning signal G1, the second scanning signal G2, the control signal EM and the data signal DATA.

In the initialization stage (namely, the T1 stage), the first switch element T1, the second switch element T2, the fourth switch element T4 and the fifth switch element T5 are turned on through the first scanning signal G1 and the control signal EM; the reset signal VINT is transmit to the first node N1 through the first switch element T1, and the driving transistor DT is turned on through the voltage signal of the first node N1; the reset signal VINT is transmit to the second node through the second switch element T2 and the reset signal VINT is transmit to the third node N3 through the fifth switch element T5; the first power signal ELVDD is transmit to the fourth node N4 through the fourth switch element T4.

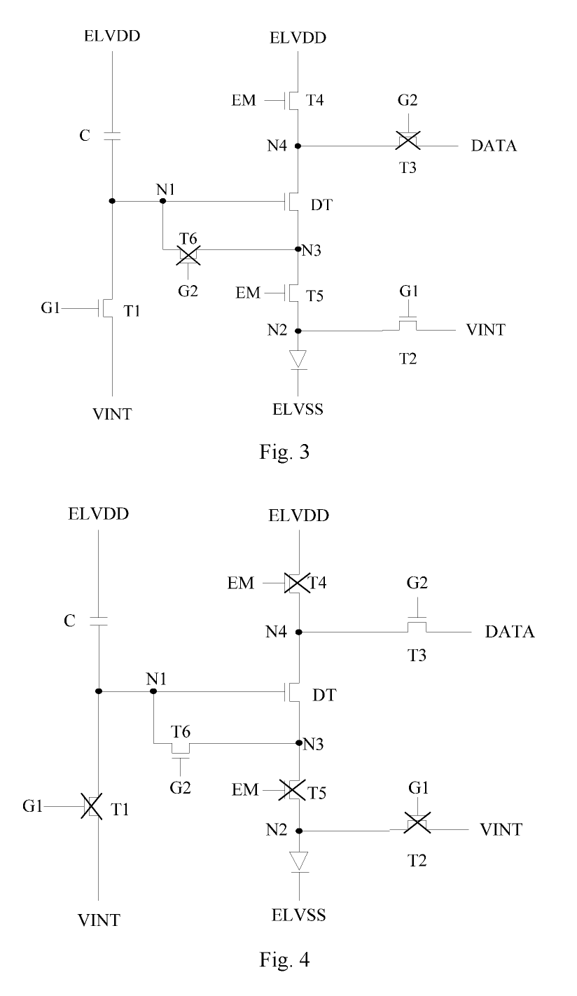

In the present exemplary embodiment, the first scanning signal G1 is low level, the second scanning signal G2 is high level, the control signal EM is low level, the data signal DATA is low level. As shown in FIG. 3, the first switch element T1, the second switch element T2, the fourth switch element T4 and the fifth switch element T5 are all turned on, the third switch element T3 and the sixth switch element T6 are all turned off; the reset signal VINT is transmitted to the first node N1 through the first switch element T1, so as to reset the control end of the driving transistor DT and recharge the first end of the storage capacitor C. At this time, the voltage of the control end of the driving transistor DT becomes VINT, and the control end of the driving transistor DT is turned on under the action of VINT; the first power signal ELVDD is transmitted to the fourth node N4 through the fourth switch element T4, so that the voltage of the first end of the driving transistor DT becomes ELVDD. At this time, the voltage between the control end and the first end of the driving transistor DT becomes VINT-ELVDD, therefore, no matter whether the voltage of the last frame of the data signal is black or white, the driving transistor DT in the basis state entering the data writing and threshold compensation stage, thus improving the problem of short term residual image caused by hysteresis effect, and improving the quality of display. In addition, the reset signal VINT is transmitted to the second node N2 through the second switch element T2, so as to reduce the voltage difference between the first electrode and the second electrode of the electroluminescent element, such that the brightness of the electroluminescent element can be reduced in low gray scales, improving the contrast of pixels.

In the data writing and threshold compensation stage, the third switch element T3 and the sixth switch element T6 are turned on through the second scanning signal G2, so as to write the data signal DATA and a threshold voltage of the driving transistor DT to the first node N1.

In the present exemplary embodiment, the first scanning signal G1 is high level, the second scanning signal G2 is low level, the control signal EM is high level, the data signal DATA is high level. As shown in FIG. 4, the third switch element T3 and the sixth switch element T6 are turned on, and the first switch element T1, the second switch element T2, the fourth switch element T4 and the fifth switch element T5 are turned off; the data signal DATA may be transmit to the fourth node N4 through the third switch element T3, at this time, because the sixth switch element T6 is turned on, making the first node N1 interconnect to the third node N3, namely the control end of the driving transistor DT is interconnected to the second end of the driving transistor DT, so as to write the data signal DATA and the threshold voltage Vth of the driving transistor DT to the first node N1, therefore, the voltage of the first node N1 becomes DATA+Vth.

In the driving stage (namely T3 stage), the fourth switch element T4 and the fifth switch element T5 are turned on through the control signal EM, so as to turn on the driving transistor DT under the control of the voltage of the first node N1 and output a driving current under the action of the first power signal ELVDD, and the driving current flows through the fifth switch element T5 to drive the electroluminescent element to emit light.

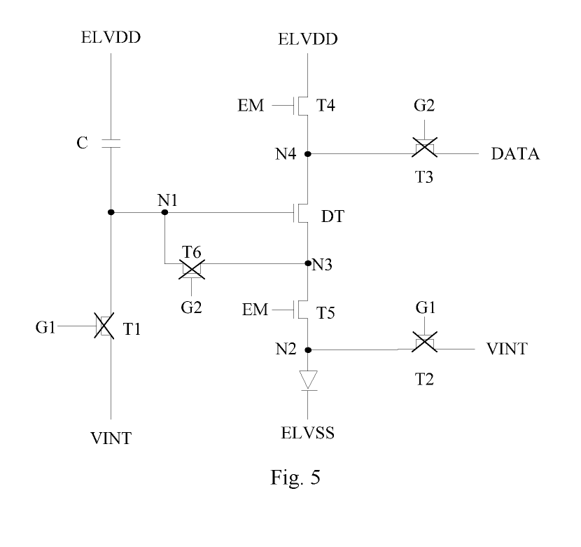

In the present exemplary embodiment, the first scanning signal G1 is high level, the second scanning signal G2 is high level, the control signal is low level, and the data signal DATA is low level. As shown in FIG. 5, the first switch element T1, the second switch element T2, the third switch element T3 and the sixth switch element T6 are turned off, the fourth switch element T4 and the fifth switch element T5 are turned on; at this time, the control end of the driving transistor DT is turned on under the control of the voltage DATA+Vth of the first node N1; the first power signal ELVDD is transmitted to the first end of the driving transistor DT through the fourth switch element T4, so as to make the voltage of the first end of the driving transistor DT become ELVDD, at this time, the driving transistor DT outputs the driving current under the action of the voltage ELVDD of the first end of the driving transistor DT, and the driving current is transmitted to the electroluminescent element through the fifth switch element T5, so as to drive the electroluminescent element to emit light.

On this basis, according to the calculation formula of the driving current of the driving transistor DT:

$$\begin{matrix}Ion = K \times {( Vgs - Vth )}^{2} = K \times {( Vg - Vs - Vth )}^{2} \\ = K \times {( DATA + Vth - ELVDD - Vth )}^{2} \\ = K \times {( DATA - ELVDD )}^{2}\end{matrix}$$

wherein, Vgs is the voltage difference between the gate and the source of the driving transistor DT, Vg is the gate voltage of the driving transistor DT, Vs is the source voltage of the driving transistor DT, and Vth is the threshold voltage of the driving transistor DT.

It is known that the driving current of the driving transistor DT is independent of the threshold voltage Vth of the driving transistor DT. From the above, in the data writing and threshold compensation stage, the third switch element T3 and the sixth switch element T6 are turned on through the second scanning signal G2, so as to interconnect the first node N1 to the third node N3, and then to write the data signal DATA and the threshold voltage Vth of the driving transistor DT to the first node N1. Thus, the influence of the threshold voltage Vth of the driving transistor DT on the driving current is eliminated, and the uniformity of the display brightness of each pixel is ensured.

The use of all P type thin film transistors has the following advantages: for example, strong noise suppression; for example, because of low level conduction, and the charge management in low level is easy to achieve; for example, P type thin film transistors have simple process and are relatively low in price; for example, P type thin film transistors have better stability and so on.

It should be noted that, in the above specific embodiments, all switch elements are P type thin film transistors; however, it is easy for those skilled in this field to obtain the pixel driving circuit of which all the switch elements are all N type thin film transistors based on the pixel driving circuit provided in the present disclosure. In an exemplary embodiment of the present disclosure, all switch elements are N type thin film transistors. Because all switch elements are N type thin film transistors, the turned on signals of the switch elements are all high level signals. Of course, the pixel driving circuit provided by the present disclosure may also be changed to CMOS (Complementary Metal Oxide Semiconductor) circuits, etc. and it is not limited to the pixel driving circuit provided in the present embodiments, the description is no longer repeated here.

The present exemplary embodiment is also provided a display device, including any one of the pixel driving circuit mentioned above. The display device including: multiple scanning lines configured to provide multiple scanning signals; multiple data lines configured to provide multiple data signals; multiple pixel driving circuits are electrically connected to the above scanning lines and data lines; at least one of the pixel driving circuits includes any one of the above pixel driving circuits in the present exemplary embodiments. Because in the reset stage, the pixel driving circuit turns on the first switch element, the second switch element, the fourth switch element and the fifth switch element through the first scanning signal and the control signal, the reset signal is transmitted to the first node through the first switch element, so as to reset the control end of the driving transistor and recharge the first end of the storage capacitor, the first power signal is transmitted to the fourth node through the fourth switch element, so as to change the voltage of the first end of the driving transistor to the voltage of the first power signal, so that the driving transistor DT in the basis state entering the data writing and threshold compensation stage, thus improving the problem of short term residual image caused by hysteresis effect no matter whether the voltage of the previous frame of the data signal is black or white, thus improving the problem of short term residual image caused by hysteresis effect and improving the quality of display; in addition, in the reset stage, turning on the second switch element through the first scanning signal, making the reset signal transmit to the second node through the second switch element, so as to reduce the voltage difference between the first electrode and the second electrode of the electroluminescent element, the brightness of the electroluminescent element can be reduced in low gray scale, improving the contrast of pixels; in addition, in the data writing and threshold compensation stage, turning on the third switch element and the sixth switch element through the second scanning signal, so as to interconnect the first node to the third node, and further may write the data signal and the threshold voltage of the driving transistor to the first node, so as to eliminate the influence of the threshold voltage of the driving transistor on the driving current, and ensure the uniformity of the brightness of each pixel. The display device may include any product or component with a display function, such as a mobile phone, a tablet computer, a TV set, a notebook computer, a digital photo frame, a navigator, and so on.

It should be noted that that the details of each module unit in the display device have been described in detail in the corresponding pixel drive circuit, so it is no longer described again herein.

It should be noted that although the above mentioned detailed descriptions refer to several modules or units used for the execution of the device, this division is not mandatory. In fact, according to the embodiments of the present disclosure, the features and functions of the two or more modules or units described above can be materialized in a module or unit. Conversely, the characteristics and functions of a module or unit described above can be further divided into several modules or units.

In addition, although each step of the method in the present disclosure is described in a particular order in the attached diagram, it does not require or imply that these steps must be performed in this particular order, or that all the steps shown must be performed to achieve the desired results. Additional or optional, some steps can be omitted, multiple steps are merged into one step, and/or a step is decomposed into multiple steps.

Other embodiments of the disclosure will be apparent to those skilled in the art from consideration of the specification and practice of the disclosure disclosed here. This application is intended to cover any variations, uses, or adaptations of the disclosure following the general principles thereof and including such departures from the present disclosure as come within known or customary practice in the art. It is intended that the specification and examples be considered as exemplary only, with a true scope and spirit of the disclosure being indicated by the following claims.

What is claimed is:

1. A pixel driving circuit, which is configured to drive an electroluminescent element, the pixel driving circuit comprising:
a first switch element, connected to a first node and configured to be turned on to transmit a reset signal to the first node in response to a first scanning signal;
a second switch element, connected to a second node, and configured to be turned on in response to the first scanning signal, so as to transmit the reset signal to the second node;
a third switch element, connected to a fourth node, and configured to be turned on in response to a second scanning signal, so as to transmit a data signal to the fourth node;
a fourth switch element, connected to the fourth node, and configured to be turned on in response to a control signal, so as to transmit a first power signal to the fourth node;
a fifth switch element, connected to the second node and a third node and configured to be turned on to electrically interconnect the third node to the second node in response to the control signal, wherein the second node is coupled with the electroluminescent element;
a sixth switch element, connected to the first node and the third node, and configured to be turned on in response to the second scanning signal, so as to interconnect the first node to the third node;
a driving transistor, connected to the third node and the fourth node, and configured to be turned on in response to a voltage signal of the first node, so as to transmit a signal of the fourth node to the third node; and
a storage capacitor, wherein a first end of the storage capacitor is coupled with the first node, and a second end of the storage capacitor receives the first power signal.

2. The pixel driving circuit according to claim 1, wherein the first, the second, the third, the fourth, the fifth and the sixth switch elements and the driving transistor each have a control end, a first end and a second end respectively, wherein:
the control end of the first switch element receives the first scanning signal, the first end of the first switch element is coupled with the first node, the second end of the first switch element receives the reset signal;
the control end of the second switch element receives the first scanning signal, the first end of the second switch element is coupled with the second node, the second end of the second switch element receives the reset signal;
the control end of the third switch element receives the second scanning signal, the first end of the third switch element receives the data signal, the second end of the third switch element is coupled with the fourth node;
the control end of the fourth switch element receives the control signal, the first end of the fourth switch element receives the first power signal, the second end of the fourth switch element is coupled with the fourth node;
the control end of the fifth switch element receives the control signal, the first end of the fifth switch element is coupled with the third node, the second end of the fifth switch element is coupled with the second node;
the control end of the sixth switch element receives the second scanning signal, the first end of the sixth switch element is coupled with the first node, the second end of the sixth switch element is coupled with the third node;
the control end of the driving transistor is coupled with the first node, the first end of the driving transistor is coupled with the fourth node, the second end of the driving transistor is coupled with the third node.

3. The pixel driving circuit according to claim 2, wherein the pixel driving circuit is connected to line N and line N+1 of scan signal lines; wherein, the line N of the scan signal lines is configured to output the first scanning signal, the line N+1 of the scan signal lines is configured to output the second scanning signal; wherein N is a positive integer.

4. The pixel driving circuit according to claim 3, wherein the switch element and the driving transistor are all P type thin film transistors, the first power signal is a high level signal, an anode of the electroluminescent element is coupled with the second node, a cathode of the electroluminescent element receives a low level signal.

5. The pixel driving circuit according to claim 3, wherein the switch element and the driving transistor are all N type thin film transistors, the first power signal is a low level signal, a cathode of the electroluminescent element is coupled with the second node, an anode of the electroluminescent element receives a high level signal.

6. The pixel driving circuit according to claim 4, wherein the thin film transistors are one of amorphous silicon thin film transistors, polycrystalline silicon thin film transistors, and amorphous-indium gallium zinc thin film transistors.

7. The pixel driving circuit according to claim 5, wherein the thin film transistors are one of amorphous silicon thin film transistors, polycrystalline silicon thin film transistors, and amorphous-indium gallium zinc thin film transistors.

8. A pixel driving method for driving a pixel driving circuit configured to drive a electroluminescent element, the pixel driving circuit comprises: a first switch element, connected to a first node, and configured to be turned on in response to a first scanning signal, so as to transmit a reset signal to the first node; a second switch element, connected to a second node, and configured to be turned on in response to the first scanning signal, so as to transmit the reset signal to the second node; a third switch element, connected to a fourth node, and configured to be turned on in response to a second scanning signal, so as to transmit a data signal to the fourth node; a fourth switch element, connected to the fourth node, and configured to be turned on in response to a control signal, so as to transmit a first power signal to the fourth node; a fifth switch element, connected to the second node and a third node, and configured to be turned on in response to the control signal, so as to interconnect the third node to the second node, and wherein the second node is coupled with the electroluminescent element; a sixth switch element, connected to the first node and the third node, and configured to be turned on in response to the second scanning signal, so as to interconnect the first node to the third node; a driving transistor, connected to the third node and the fourth node, and configured to be turned on in response to a voltage signal of the first node, so as to transmit a signal of the fourth node to the third node; and a storage capacitor, wherein a first end of the storage capacitor is coupled with the first node, and a second end of the storage capacitor receives the first power signal; the method comprising:
in a reset stage, the first switch element, the second switch element, the fourth switch element and the fifth switch element are turned on through the first scanning signal and the control signal; the reset signal is transmit to the first node through the first switch element, and the driving transistor is turned on through the voltage signal of the first node; the reset signal is transmit to the second node through the second switch element and the reset signal is transmit to the third node through the fifth switch element; the first power signal is transmit to the fourth node through the fourth switch element;
in a data writing and threshold compensation stage, the third switch element and the sixth switch element are turned on through the second scanning signal, so as to write the data signal and a threshold voltage of the driving transistor to the first node; and
in a driving stage, the fourth switch element and the fifth switch element are turned on through the control signal, so as to turn on the driving transistor under the control of the voltage of the first node and output a driving current under the action of the first power signal, and the driving current flows through the fifth switch element to drive the electroluminescent element to emit light.

9. The pixel driving method according to claim 8, wherein all the switch elements are P type thin film transistors, and each of the switch elements is turned on through a low level signal.

10. The pixel driving method according to claim 8, wherein when all the switch elements are N type thin film transistors, and each of the switch elements is turned on through a high level signal.

11. A display device, comprising a pixel driving circuit configured to drive an electroluminescent element, the pixel driving circuit comprising:
a first switch element, connected to a first node, and configured to be turned on in response to a first scanning signal, so as to transmit a reset signal to the first node;
a second switch element, connected to a second node, and configured to be turned on in response to the first scanning signal, so as to transmit the reset signal to the second node;
a third switch element, connected to a fourth node, and configured to be turned on in response to a second scanning signal, so as to transmit a data signal to the fourth node;
a fourth switch element, connected to the fourth node, and configured to be turned on in response to a control signal, so as to transmit a first power signal to the fourth node;
a fifth switch element, connected to the second node and a third node, and configured to be turned on in response to the control signal, so as to interconnect the third node to the second node, and the second node is coupled with the electroluminescent element;
a sixth switch element, connected to the first node and the third node, and configured to be turned on in response to the second scanning signal, so as to interconnect the first node to the third node;
a driving transistor, connected to the third node and the fourth node, and configured to be turned on in response to a voltage signal of the first node, so as to transmit a signal of the fourth node to the third node; and
a storage capacitor, a first end of the storage capacitor is coupled with the first node, and a second end of the storage capacitor receives the first power signal.

12. The display device according to claim 11, wherein the first switch element to the sixth switch element and the driving transistor have a control end, a first end and a second end respectively, wherein:
the control end of the first switch element receives the first scanning signal, the first end of the first switch element is coupled with the first node, the second end of the first switch element receives the reset signal;
the control end of the second switch element receives the first scanning signal, the first end of the second switch element is coupled with the second node, the second end of the second switch element receives the reset signal;
the control end of the third switch element receives the second scanning signal, the first end of the third switch element receives the data signal, the second end of the third switch element is coupled with the fourth node;
the control end of the fourth switch element receives the control signal, the first end of the fourth switch element receives the first power signal, the second end of the fourth switch element is coupled with the fourth node;
the control end of the fifth switch element receives the control signal, the first end of the fifth switch element is coupled with the third node, the second end of the fifth switch element is coupled with the second node;
the control end of the sixth switch element receives the second scanning signal, the first end of the sixth switch element is coupled with the first node, the second end of the sixth switch element is coupled with the third node;
the control end of the driving transistor is coupled with the first node, the first end of the driving transistor is coupled with the fourth node, the second end of the driving transistor is coupled with the third node.

13. The display device according to claim 12, wherein the pixel driving circuit is connected to line N and line N+1 of scan signal lines; wherein, the line N of the scan signal line is configured to output the first scanning signal, the line N+1 of the scan signal line is configured to output the second scanning signal; N is a positive integer.

14. The display device according to claim 13, wherein the switch element and the driving transistor are all P type thin film transistors, the first power signal is a high level signal, an anode of the electroluminescent element is coupled with the second node, a cathode of the electroluminescent element receives a low level signal.

15. The display device according to claim 13, wherein the switch element and the driving transistor are all N type thin film transistors, the first power signal is a low level signal, a cathode of the electroluminescent element is coupled with the second node, an anode of the electroluminescent element receives a high level signal.

16. The display device according to claim 14, wherein the thin film transistors can be one of amorphous silicon thin film transistors, polycrystalline silicon thin film transistors, and amorphous-indium gallium zinc thin film transistors.

17. The display device according to claim 15, wherein the thin film transistors can be one of amorphous silicon thin film transistors, polycrystalline silicon thin film transistors, and amorphous-indium gallium zinc thin film transistors.
